(19) United States
(12) Patent Application Publication
(10) Pub. No.: US 2026/0089840 A1
(43) Pub. Date: Mar. 26, 2026

(54) CIRCUIT BOARD AND FABRICATING METHOD OF THE SAME

(71) Applicants: Avary Holding (Shenzhen) Co., Ltd., Shenzhen (CN); HongHengShen Electronical Technology(Huai’an)Co., Ltd., Jiangsu Province (CN); Garuda Technology Co., Ltd., New Taipei City (TW)

(72) Inventors: Ping LI, Shenzhen (CN); Ming-Jun CHEN, Shenzhen (CN); Yu-Feng DAI, Shenzhen (CN); Wen-Qian LIN, Shenzhen (CN)

(21) Appl. No.: 18/896,007

(22) Filed: Sep. 25, 2024

(51) Int. Cl. H05K 1/11; H05K 1/02; H05K 3/10; H05K 3/42

(52) U.S. Cl. CPC H05K 1/115; H05K 1/0298; H05K 3/107; H05K 3/429; H05K 2201/09509; H05K 2203/107

(57) ABSTRACT

A circuit board and a fabricating method of the same are provided. The circuit board includes multiple first wiring layers, a plated through hole, a filling material, a cover wiring layer, a second wiring layer and a conductive structure. The plated through hole extends through the first wiring layers and is electrically connected to the first wiring layers. The filling material is disposed in the plated through hole. The cover wiring layer covers the plated through hole and is electrically connected to the plated through hole. The second wiring layer is stacked on the first wiring layers and the cover wiring layer. The conductive structure extends through the cover wiring layer to the filling material from the second wiring layer and is inserted in the filling material. The conductive structure does not penetrate the filling material.

### BACKGROUND

### Technical Field

The present application relates to a circuit board and a fabricating method of the same.

### Description of Prior Art

With the miniaturization and multi-functionalization of electronic products, the electronic products can employ high density interconnector (HDI) circuit boards. In the HDI circuit boards, a via on PTH (VOP) technology can be used. This technology is to set resin in a PTH after the PTH is formed in a circuit board. A copper layer is then plated to seal the resin in the PTH. Next, a wiring layer is stacked on the copper layer and a conductive blind via is formed, where the conductive blind via is electrically connected to the wiring layer and the copper layer.

However, in the current VOP technology, the copper layer does not have a good binding force with the resin. In the process of forming the conductive blind via, it is necessary to use a laser beam with an extremely high temperature, i.e., extremely high energy, to drill holes, and the temperature is not easy to disperse, so that the copper layer and the resin are easily separated by splitting. In order to improve this deficiency, it is necessary to increase the thickness of the copper layer to improve the heat conduction effect, for example, the thickness of the copper layer is increased to 20 microns. However, such manner causes the width of tracks and a pitch between the tracks to increase. For example, the width of the track is increased to 100 microns and the pitch between the tracks is also increased to 100 microns.

### SUMMARY

At least one embodiment of the present application provides a circuit board and a fabricating method of the same, wherein the circuit board may employ the VOP technology, and the fabricating method will not increase the width of tracks and a pitch between the tracks.

The circuit board provided in the at least one embodiment of the present application comprises multiple first wiring layers, a plated through hole, a filling material, a cover wiring layer, a second wiring layer and a conductive structure. The multiple first wiring layers are stacked. The plated through hole extends through the multiple first wiring layers and is electrically connected to the multiple first wiring layers. The filling material is disposed in the plated through hole. The cover wiring layer covers the plated through hole and is electrically connected to the plated through hole. The second wiring layer is stacked on the multiple first wiring layers and the cover wiring layer. The conductive structure extends through the cover wiring layer to the filling material from the second wiring layer and is inserted in the filling material. The conductive structure is electrically connected to the second wiring layer and the cover wiring layer and does not penetrate the filling material.

The fabricating method of the circuit board provided in the at least one embodiment of the present application comprises: providing a baseboard, wherein the baseboard comprises multiple first metal layers, a plated through hole and a filling material, wherein the multiple first metal layers are stacked, the plated through hole extends through the multiple first metal layers and is electrically connected to the multiple first metal layers, and the filling material is disposed in the plated through hole; forming a cover metal layer on the multiple first metal layers; forming a via hole on the cover metal layer to form a cover wiring layer, wherein the via hole reveals the filling material; after the via hole is formed, stacking a second metal layer on the cover wiring layer; after the second metal layer is stacked, forming a groove, wherein the groove extends through the cover wiring layer to part of the filling material from the second metal layer, wherein the groove overlaps the via hole; and forming a conductive structure in the groove, wherein the conductive structure is inserted in the filling material and electrically connected to the second metal layer and the cover wiring layer.

Based on the above, in the circuit board disclosed in the above embodiment, the conductive structure is inserted in the filling material to increase a contact area with the filling material, thereby improving a heat dissipation effect and reducing the splitting of the cover wiring layer and the filling material without increasing the width of tracks and a pitch between the tracks.

### BRIEF DESCRIPTION OF THE DRAWINGS

For a more complete understanding of embodiments and their advantages, the following description is made with reference to the drawings in which:

FIG. 1 is a partial sectioned view of a circuit board according to at least one embodiment of the present application;

FIG. 2 is a partial enlarged view of FIG. 1;

FIG. 3 is a sectional view of a step of providing a baseboard in a fabricating method of the circuit board in FIG. 1;

FIG. 4 is a sectional view of a step of forming cover metal layers in the fabrication method of the circuit board in FIG. 1;

FIG. 5 is a sectional view of a step of forming cover wiring layers and wiring layers in the fabrication method of the circuit board in FIG. 1;

FIG. 6 is a sectional view of a step of stacking baseboards in the fabrication method of the circuit board in FIG. 1;

FIG. 7 is a sectional view of a step of forming grooves in the fabrication method of the circuit board in FIG. 1; and

FIG. 8 is a sectional view of a step of forming conductive structures in the fabrication method of the circuit board in FIG. 1.

### DETAILED DESCRIPTION

For clearly introducing the technical features of the present application below, the dimensions (such as length, width, thickness, and depth) of components (such as layers, membranes, baseboards, and areas) in the figures will be scaled up disproportionately, and the number of some components will be reduced. Accordingly, the description and interpretation of the embodiments below shall not be limited to the number of components and the dimensions and shapes of the components shown in the figures, but shall encompass dimensions, shapes and deviations therebetween as a result of actual manufacturing processes and/or tolerances. For example, a flat surface shown in a figure may have a feature of roughness and/or nonlinearity, while an acute angle shown in a figure may be circular. Therefore, the components shown in the present application are mainly used for schematic purposes, and are not intended to accurately depict the actual shapes of the components, nor are they used to limit the claims of the patent application.

Secondly, the words “about”, “approximately” or “substantially” appearing herein encompass not only clearly recorded values and ranges of the values, but also allowable deviation ranges understood by persons of ordinary skill in the art, wherein the deviation ranges may be determined by errors resulting from measurements, and the errors are due, for example, to limitations of both a measuring system and process conditions. In addition, “about” can mean within one or more standard deviations of the above values, such as ±30%, ±20%, ±10% or ±5%. The terms “about”, “approximately” or “substantially” as used in the present application may be used to select acceptable deviations ranges or standard deviations based on optical, etchable, mechanical or other properties, rather than a single standard deviation to apply all of the above optical, etchable, mechanical or other properties. In addition, for the purpose of clearly illustrating the following embodiments, functionally identical or similar components are indicated by reference numerals.

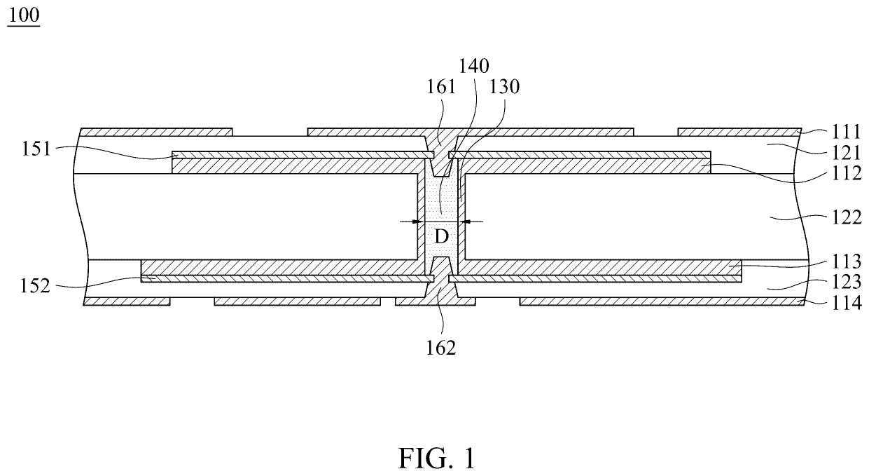

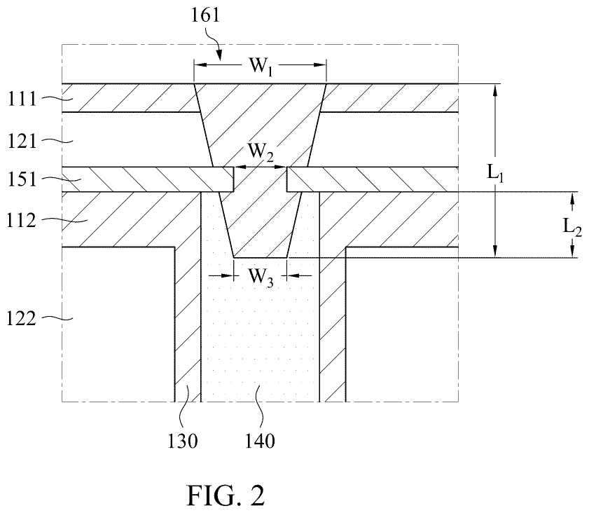

FIG. 1 is a partial sectioned view of a circuit board 100 according to at least one embodiment of the present application, and FIG. 2 is a partial enlarged view of FIG. 1. Referring to FIGS. 1 and 2, the circuit board 100 includes multiple wiring layers 111-114, multiple dielectric layers 121-123, a plated through hole 130, a filling material 140, multiple cover wiring layers 151, 152, and multiple conductive structures 161, 162. The circuit board 100 may be an HDI circuit board, but is not limited to this.

In an example shown in FIG. 1, the circuit board 100 includes four wiring layers 111-114 and three dielectric layers 121-123, but is not limited to this. The dielectric layers 121-123 and the wiring layers 111-114 are stacked, where the dielectric layer 121 is sandwiched between the adjacent wiring layers 111 and 112, the dielectric layer 122 is sandwiched between the adjacent wiring layers 112 and 113, and the dielectric layer 123 is sandwiched between the adjacent wiring layers 113 and 114.

The plated through hole 130 extends through the multiple wiring layers 112, 113 and the dielectric layer 122, and is electrically connected to the multiple wiring layers 112 and 113. The filling material 140 is disposed in the plated through hole 130, and is filled in the plated through hole 130 to be flush with outer surfaces of the wiring layers 112 and 113 (i.e., the outer surfaces of the wiring layers 112 and 113 relative to a core dielectric layer, where the core dielectric layer is the dielectric layer 122). The filling material 140 may be resin. The cover wiring layer 151 is sandwiched between the wiring layer 112 and the dielectric layer 121, and the cover wiring layer 152 is sandwiched between the wiring layer 113 and the dielectric layer 123.

The cover wiring layers 151, 152 respectively cover upper and lower openings of the plated through hole 130 and are in contact with the filling material 140. The cover wiring layers 151, 152 are electrically connected to the wiring layers 112, 113 and the plated through hole 130. An aperture D of the plated through hole 130 may be 0.15-0.3 mm. The cover wiring layers 151, 152 each may have a thickness of a minimum of 5 microns or greater than 5 microns.

The conductive structures 161, 162 are roughly columnar. The conductive structure 161 extends through the dielectric layer 121 and the cover wiring layer 151 to the filling material 140 from the wiring layer 111. The conductive structure 161 is inserted in the filling material 140 and does not penetrate the filling material 140. Similarly, the conductive structure 162 extends through the dielectric layer 123 and the cover wiring layer 152 to the filling material 140 from the wiring layer 114. The conductive structure 162 is inserted in the filling material 140 and does not penetrate the filling material 140. In other words, the conductive structures 161, 162 are partially inserted and embedded in the filling material 140. The thicknesses of the dielectric layers 121, 123 may be 100-125 microns.

The conductive structure 161 is electrically connected to the wiring layer 111 and the cover wiring layer 151 such that the conductive structure 161 is also electrically connected to the plated through hole 130, the wiring layers 112, 113 and 114 and the cover wiring layer 152. Similarly, the conductive structure 162 is electrically connected to the wiring layer 114 and the cover wiring layer 152 such that the conductive structure 162 is also electrically connected to the plated through hole 130, the wiring layers 111, 112 and 113 and the cover wiring layer 151.

Further, the widths of the conductive structures 161, 162 are gradually reduced in a direction away from the wiring layers 111, 114. The conductive structures 161, 162 may be conductive blind vias. Therefore, the circuit board 100 may employ the VOP technology. It should be noted that in other embodiments, other wiring layers can be stacked on the wiring layers 111, 114, so that the conductive structures 161, 162 may be conductive buried vias.

In detail, the conductive structures 161, 162 each have a first width W1 at positions corresponding to the outer surfaces of the wiring layers 111, 114 (i.e., the outer surfaces of the wiring layers 111, 114 relative to the dielectric layer 122), and a second width W₂ at positions corresponding to the outer surfaces of the cover wiring layers 151, 152 (i.e., the outer surfaces of the cover wiring layers 151, 152 relative to the dielectric layer 122). Furthermore, the conductive structures 161, 162 each have a bottom extending to the filling material 140, and the bottom has a third width W₃. The first width W₁ can be 125-150 microns. The second width W₂ can be 100-150 microns. A ratio of the second width W₂ to the first width W₁ can be 0.8-1. A ratio of the third width W₃ to the second width W₂ can be 0.8-1.

Further, the conductive structures 161, 162 each have a first extension length L₁ and a second extension length L₂. The first extension length L₁ is a length of the conductive structure 161 or 162 extending from the outer surface of the wiring layer 111 or 114 to the inside of the filling material 140, where as shown in FIG. 2, the first extension length L₁ is an overall length of the conductive structure 161 or 162, and the first extension length L₁ can be 100-125 microns.

The second extension length L₂ is a length extending from the inner surface of the cover wiring layer 151 or 152 (i.e., the inner surface of the cover wiring layer 151 or 152 relative to the dielectric layer 122) to the inside of the filling material 140. That is, the second extension length L₂ is a length of the conductive structure 161 or 162 inserted in the filling material 140. The second extension length L₂ can be 40-70 microns. A ratio of the second extension length L₂ to the first extension length L₁ can be 1/3-1/2. An aspect ratio of the conductive structures 161, 162 can be 0.6-0.9. That is, a ratio of the first extension length L₁ to the first width W₁ of the conductive structure 161 or 162 can be 0.6-0.9.

It should be noted that since the conductive structures 161 and 162 are identical or similar in structure, that is, the conductive structures 161 and 162 each have the first extension length L₁, the second extension length L₂, the first width W₁ and the second width W₂, the conductive structure 161 is selected as an example in FIG. 2 of the present application to describe the features of the first extension length L₁, the second extension length L₂, the first width W₁ and the second width W₂.

Since the conductive structures 161, 162 are inserted in the filling material 140, areas of the conductive structures 161, 162 in contact with the filling material 140 are increased, thereby improving the heat dissipation effect and reducing the splitting of the cover wiring layers 151, 152 and the filling material 140. As a result, the circuit board 100 can reduce the splitting of the cover wiring layers 151, 152 and the filling material 140 without thickening the cover wiring layers 151, 152, thereby reducing the width of tracks and a pitch between the tracks. For example, the width of the track can be reduced to 40 microns, and the pitch between the tracks can be reduced to 40 microns. Secondly, the conductive structures 161, 162 are connected to the cover wiring layers 151, 152 and are inserted in the filling material 140, thereby increasing binding forces between the cover wiring layers 151, 152 and the filling material 140. In addition, the cover wiring layers 151, 152 are embedded in the conductive structures 161, 162, which also increase the binding forces between the cover wiring layers 151, 152 and the conductive structures 161, 162.

A drawing force test is performed on the conductive structures 161, 162. After several drawing force tests, the drawing forces for separating the cover wiring layers 151, 152 from the filling material 140 can reach 179.601 kgf/cm², 171.083 kgf/cm² and 164.066 kgf/cm² (as shown in Table 1 below), which are much higher than a drawing force for separating a copper layer from resin in the current VOP technology (as shown in Table 2 below).

TABLE 1
Drawing Force Tests on the Conductive
Structures in the Present Application

| | First Test | Second Test | Third Test |
|---|---|---|---|
| Structure Parameter | Result | Result | Result |
| First Width W₁ | 122.45 | 121.54 | 118.37 |
| (micron) | | | |
| Second Width W₂ | 99.08 | 98.62 | 95.53 |
| (micron) | | | |
| Third Width W₃ | 81.55 | 80.15 | 82.33 |
| (micron) | | | |
| First Extension Length L₁ | 108.57 | 106.39 | 107.42 |
| (micron) | | | |
| Second Extension Length L₂ | 42.63 | 43.15 | 43.69 |
| (micron) | | | |
| Drawing Force | 179.601 | 171.083 | 164.066 |
| (kgf/cm²) | | | |

TABLE 2
Drawing Forces Test on General Conductive
Blind Vias (VOP technology)

| | First Test | Second Test | Third Test |
|---|---|---|---|
| Structure Parameter | Result | Result | Result |
| Upper Aperture Width | 120.24 | 119.56 | 120.87 |
| (micron) | | | |
| Lower Aperture Width | 97.39 | 95.64 | 99.56 |
| (micron) | | | |
| Depth (micron) | 105.17 | 104.55 | 104.88 |
| Drawing Force | 45.959 | 41.632 | 48.165 |
| (kgf/cm²) | | | |

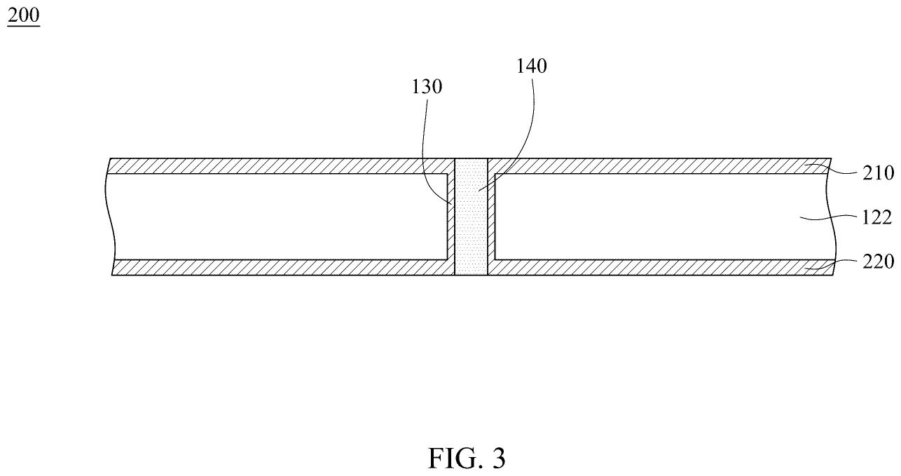

FIG. 3 is a sectional view of a step of providing a baseboard 200 in a fabricating method of the circuit board 100 in FIG. 1. Referring to FIG. 3, the baseboard 200 is provided. The baseboard 200 includes multiple metal layers 210, 220 and a dielectric layer 122. The dielectric layer 122 is sandwiched between the metal layers 210 and 220. The baseboard 200 is then drilled to form a through hole penetrating the metal layers 210, 220 and the dielectric layer 122, where the through hole can be formed by means of laser drilling or mechanical drilling. Next, the inner wall surface of the through hole is metallized to form the plated through hole 130, for example, a metal layer is formed on the inner wall of the through hole by means of Plating Through Hole (PTH).

Therefore, the plated through hole 130 extends through the metal layers 210, 220 and the dielectric layer 122 and is electrically connected to the metal layers 210 and 220. Next, the filling material 140 is disposed in the plated through hole 130. The outer surfaces of the metal layers 210, 220 and the filling material 140 are then ground so that the outer surfaces of the metal layers 210, 220 and the filling material 140 are flush.

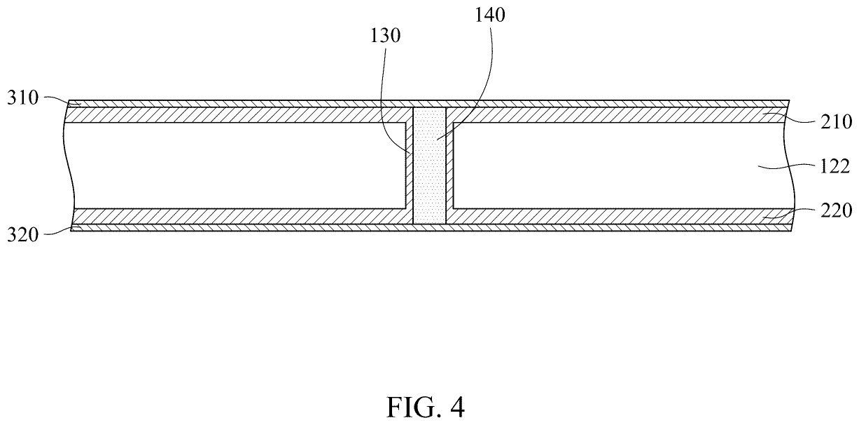

FIG. 4 is a sectional view of a step of forming cover metal layers 310, 320 in the fabrication method of the circuit board 100 in FIG. 1. Referring to FIG. 4, the cover metal layers 310, 320 are formed on the metal layers 210, 220 and the filling material 140, for example, the cover metal layers 310, 320 are formed by means of plating. The cover metal layers 310, 320 cover the metal layers 210, 220 and the upper and lower openings of the plated through hole 130, respectively, and are in contact with the filling material 140. The cover metal layers 310, 320 are electrically connected to the metal layers 210, 220 and the plated through hole 130.

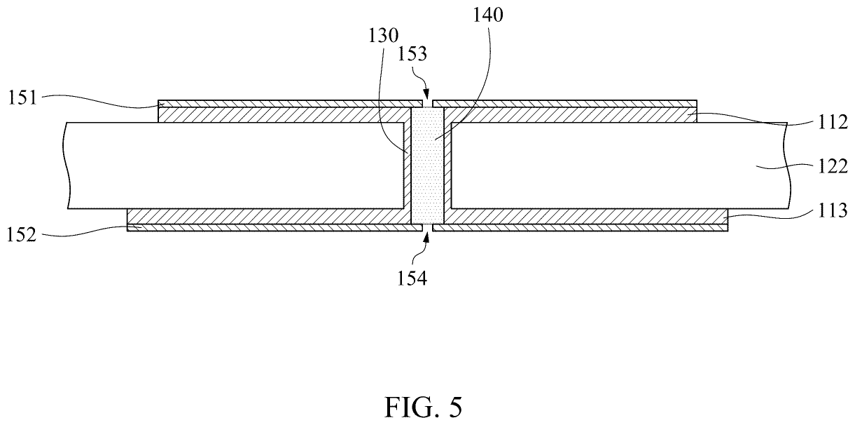

FIG. 5 is a sectional view of a step of forming the cover wiring layers 151, 152 and the wiring layers 112, 113 in the fabrication method of the circuit board in FIG. 1. Referring to FIG. 5, the cover metal layers 310, 320 and the metal layers 210, 220 are patterned to form the cover wiring layers 151, 152 and the wiring layers 112, 113, respectively. The cover wiring layers 151, 152 and the wiring layers 112, 113 can be formed by an etching process. In particular, the cover wiring layers 151, 152 have a plurality of via holes 153, 154, respectively. These via holes 153, 154 reveal the filling material 140. Further, the apertures of the via holes 153, 154 are smaller than the second width W₂.

For example, the apertures of the via holes 153, 154 can be at least 10 microns smaller than the second width W₂. For example, when the second width W₂ is 100 microns, the apertures of the via holes 153, 154 are 90 microns. It is worth mentioning that these via holes 153, 154 are formed by using lithography and etching processes, so that the sizes of the via holes 153, 154 can be ensured. In other words, the lithography and etching processes can control the sizes of the via holes 153, 154, so as to avoid that the via holes 153, 154 have improper sizes. For example, when the sizes of the via holes 153, 154 are too large, the conductive structures 161, 162 formed later may not be electrically connected to the cover wiring layers 151, 152.

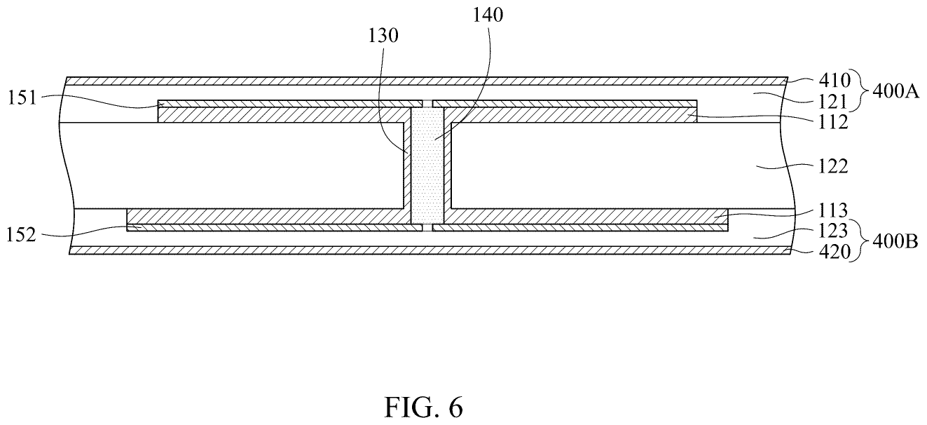

FIG. 6 is a sectional view of a step of stacking baseboards 400A, 400B in the fabrication method of the circuit board 100 in FIG. 1. Referring to FIG. 6, the baseboard 400A formed by a metal layer 410 and the dielectric layer 121 is stacked on the cover wiring layer 151, and the dielectric layer 121 is sandwiched between the cover wiring layer 151 and the metal layer 410. The baseboard 400B formed by a metal layer 420 and the dielectric layer 123 is stacked on the cover wiring layer 152, and the dielectric layer 123 is sandwiched between the cover wiring layer 152 and the metal layer 420.

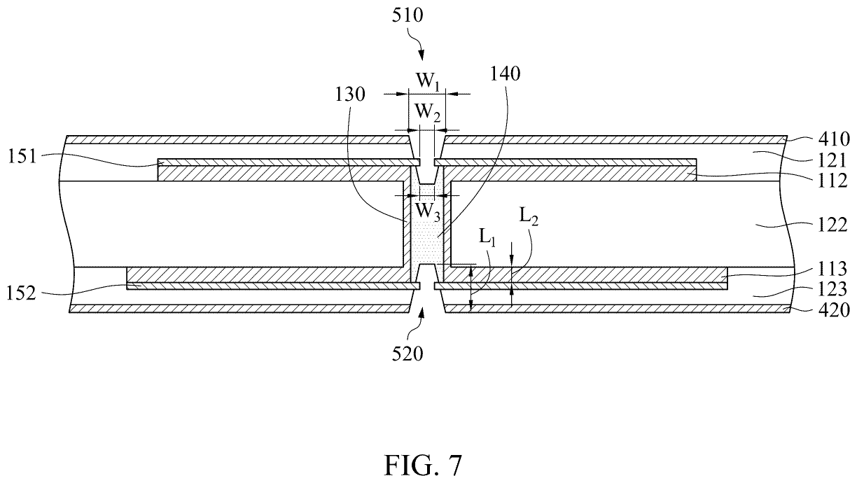

FIG. 7 is a sectional view of a step of forming grooves 510, 520 in the fabrication method of the circuit board 100 in FIG. 1. Referring to FIG. 7, the grooves 510, 520 are formed. The groove 510 extends through the dielectric layer 121, the cover wiring layer 151 and the wiring layer 112 to part of the filling material 140 from the metal layer 410. The groove 520 extends through the dielectric layer 123, the cover wiring layer 152 and the wiring layer 113 to part of the filling material 140 from the metal layer 420. The groove 510 overlaps the via hole 153 (shown in FIG. 5), and the groove 520 overlaps the via holes 154 (shown in FIG. 5). The grooves 510, 520 can be formed by a laser process, e.g., laser ablation.

Further, the grooves 510, 520 each have an aperture of the first width W₁ at positions corresponding to the outer surfaces of the metal layers 410, 420 (i.e., the outer surfaces of the metal layers 410, 420 relative to the dielectric layer 122). The grooves 510, 520 each have an aperture of the second width W₂ at positions corresponding to the outer surfaces of the cover wiring layers 151, 152. The bottoms of the grooves 510, 520 each have an aperture of the third width W₃. The apertures of the grooves 510, 520 at the positions corresponding to the via holes 153, 154 (the aperture of the second width W₂) are greater than the apertures of the via holes 153, 154. It should be noted that the grooves 510, 520 can be ablated by a laser beam emitted by a carbon dioxide laser, and the laser beam is infrared light. In the ablation process, the filling material 140 is ablated more easily than the cover wiring layers 151, 152. Therefore, the apertures of the grooves 510, 520 at positions of the filling material 140 close to the junctions of the cover wiring layers 151, 152 can be greater than the apertures of the second width W₂.

The grooves 510, 520 each have the first extension length L₁, and the first extension length L₁ is a length extending from the outer surface of the metal layer 410 or 420 to the inside of the filling material 140. The grooves 510, 520 also each have the second extension length L₂, and the second extension length L₂ is a length extending from the inner surface of the cover wiring layer 151 or 152 to the inside of the filling material 140. The corresponding relationships among the first width W₁, the second width W₂, the third width W₃, the first extension length L₁ and the second extension length L₂ of the grooves 510, 520 are described above and will not be repeated here.

It is worth mentioning that since the via holes 153, 154 are formed before the formation of the grooves 510, 520, the grooves 510, 520 can be formed without using a laser beam with an extremely high temperature (or extremely high energy), and the heat energy generated by the laser beam can be transmitted more quickly through the via holes 153, 154 to the filling material 140, thereby avoiding that the cover wiring layers 151, 152 are separated from the filling material 140 due to splitting.

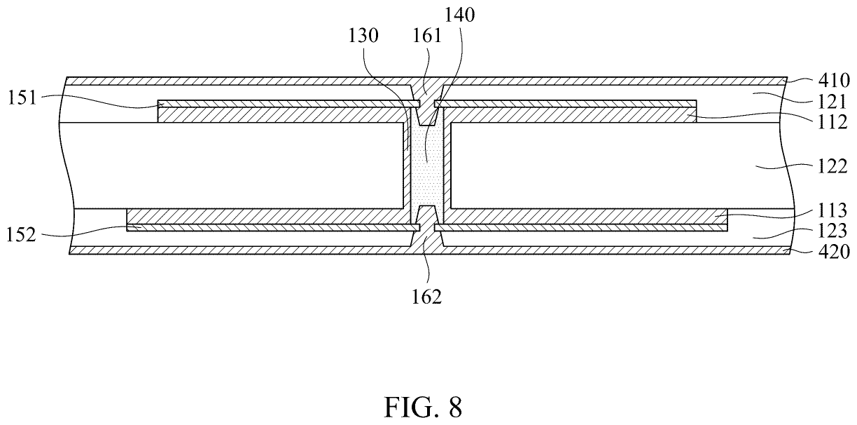

FIG. 8 is a sectional view of a step of forming the conductive structures 161, 162 in the fabrication method of the circuit board 100 in FIG. 1. Referring to FIGS. 7 and 8, the conductive structures 161, 162 are formed in the grooves 510, 520, respectively. The conductive structures 161, 162 can be formed by a plating process. The conductive structure 161 is inserted in the filling material 140 and electrically connected to the metal layer 410 and the cover wiring layer 151. The conductive structure 162 is inserted in the filling material 140 and electrically connected to the metal layer 420 and the cover wiring layer 152. The conductive structures 161, 162 each have a top relative to the bottom. The tops of the conductive structures 161, 162 are flush with the outer surfaces of the metal layers 410, 420. The metal layers 410, 420 can then be patterned by using an etching process to form the wiring layers 111, 114 (as shown in FIG. 1). As a result, the fabrication of the circuit board 100 is completed.

It is worth mentioning that, based on the corresponding relationships among the first width W₁, the second width W₂, the third width W₃, the first extension length L₁ and the second extension length L₂ of the grooves 510, 520, a plating potion is easily filled in the grooves 510, 520 to ensure a smooth plating process. In addition, based on the corresponding relationships among the first width W₁, the second width W₂, the third width W₃, the first extension length L₁ and the second extension length L₂ of the conductive structures 161, 162, the conductive structures 161, 162, the cover wiring layers 151, 152 and the filling material 140 form a good binding force. The conductive structures 161, 162 can achieve a balance between the formation process and the formation of the binding force.

In summary, in the circuit board 100 disclosed in the above embodiment, the conductive structures 161, 162 are inserted in the filling material 140 to increase the contact area with the filling material 140, thereby improving the heat dissipation effect and reducing the splitting of the cover wiring layers 151, 152 and the filling material 140. Furthermore, the circuit board 100 can reduce the splitting of the cover wiring layers 151, 152 and the filling material 140 without thickening the cover wiring layers 151, 152, thereby reducing the width of tracks and a pitch between the tracks. Secondly, since the conductive structures 161, 162 are connected to the cover wiring layers 151, 152 and inserted in the filling material 140, the binding forces between the conductive structures 161, 162 as well as the cover wiring layers 151, 152, and the filling material 140 are enhanced.

In addition, in the fabricating method of the circuit board 100, the via holes 153, 154 are formed before the formation of the grooves 510, 520, the grooves 510, 520 can be formed without using a laser beam with an extremely high temperature (or extremely high energy), and the heat energy generated by the laser beam can be transmitted more quickly through the via holes 153, 154 to the filling material 140, thereby avoiding that the cover wiring layers 151, 152 are separated from the filling material 140 due to splitting. Furthermore, the via holes 153, 154 are formed using an etching process, so that the sizes of the via holes 153, 154 are ensured.

Although the present application has been disclosed as above in embodiments, the embodiments are not intended to limit the present application, and those of ordinary skill in the art may make some changes and embellishments within the spirit and scope of the present application, so that the scope of protection of the invention shall be defined in the attached claims.

What is claimed is:

1. A circuit board, comprising:
multiple first wiring layers that are stacked;
a plated through hole that extends through the multiple first wiring layers and is electrically connected to the multiple first wiring layers;
a filling material that is disposed in the plated through hole;
a cover wiring layer that covers the plated through hole and is electrically connected to the plated through hole;
a second wiring layer that is stacked on the multiple first wiring layers and the cover wiring layer; and
a conductive structure that extends through the cover wiring layer to the filling material from the second wiring layer and is inserted in the filling material, wherein the conductive structure is electrically connected to the second wiring layer and the cover wiring layer and does not penetrate the filling material.

2. The circuit board according to claim 1, wherein a width of the conductive structure is gradually reduced in a direction away from the second wiring layer.

3. The circuit board according to claim 1, wherein the conductive structure has a first width at a position corresponding to the second wiring layer and a second width at a position corresponding to the cover wiring layer; and
a ratio of the second width to the first width is 0.8-1.

4. The circuit board according to claim 3, wherein the conductive structure has a bottom extending to the filling material, the bottom has a third width, and a ratio of the third width to the second width is 0.8-1.

5. The circuit board according to claim 1, wherein the conductive structure has a first extension length, wherein the first extension length is a length extending from the second wiring layer to the filling material;
the conductive structure has a second extension length, wherein the second extension length is a length extending from the cover wiring layer to the filling material; and
a ratio of the second extension length to the first extension length is 1/3-1/2.

6. The circuit board according to claim 1, wherein an aspect ratio of the conductive structure is 0.6-0.9.

7. The circuit board according to claim 1, wherein the conductive structure is a conductive blind via.

8. A fabricating method of a circuit board, comprising:
providing a baseboard, wherein the baseboard comprises multiple first metal layers, a plated through hole and a filling material, wherein the multiple first metal layers are stacked, the plated through hole extends through the multiple first metal layers and is electrically connected to the multiple first metal layers, and the filling material is disposed in the plated through hole;
forming a cover metal layer on the multiple first metal layers;
forming a via hole on the cover metal layer to form a cover wiring layer, wherein the via hole reveals the filling material;
after the via hole is formed, stacking a second metal layer on the cover wiring layer;
after the second metal layer is stacked, forming a groove, wherein the groove extends through the cover wiring layer to part of the filling material from the second metal layer, wherein the groove overlaps the via hole; and
forming a conductive structure in the groove, wherein the conductive structure is inserted in the filling material and is electrically connected to the second metal layer and the cover wiring layer.

9. The fabricating method according to claim 8, wherein an aperture of the groove at a position corresponding to the via hole is greater than an aperture of the via hole.

10. The fabricating method according to claim 8, wherein the via hole is formed by an etching process.

11. The fabricating method according to claim 8, wherein the groove is formed by a laser process.

12. The fabricating method according to claim 8, further comprising:
before the second metal layer is stacked, patterning the first metal layers to form multiple first wiring layers; and
after the second metal layer is stacked, patterning the second metal layer to form a second wiring layer.

13. The fabricating method according to claim 12, wherein the conductive structure has a first width at a position corresponding to the second wiring layer and a second width at a position corresponding to the cover wiring layer; and
a ratio of the second width to the first width is 0.8-1.

14. The fabricating method according to claim 13, wherein the conductive structure has a bottom extending to the filling material, the bottom has a third width, and a ratio of the third width to the second width is 0.8-1.

15. The fabricating method according to claim 12, wherein the conductive structure has a first extension length, wherein the first extension length is a length extending from the second wiring layer to the filling material;
the conductive structure has a second extension length, wherein the second extension length is a length extending from the cover wiring layer to the filling material; and
a ratio of the second extension length to the first extension length is 1/3-1/2.

16. The fabricating method according to claim 8, wherein an aspect ratio of the conductive structure is 0.6-0.9.
